(19) United States
(12) Patent Application Publication
(10) Pub. No.: US 2011/0006376 A1
(43) Pub. Date: Jan. 13, 2011

(54) SEMICONDUCTOR DEVICE, SEMICONDUCTOR DEVICE MANUFACTURING METHOD, AND DISPLAY DEVICE

(76) Inventors: Yasumori Fukushima, Osaka-shi (JP); Yutaka Takafuji, Osaka (JP); Masao Moriguchi, Osaka (JP); Kenshi Tada, Osaka (JP); Steven Roy Droes, Carnas, WA (US)

Correspondence Address: BIRCH STEWART KOLASCH & BIRCH, PO BOX 747, FALLS CHURCH, VA, 22040-0747, US

(21) Appl. No.: 12/922,119

(22) PCT Filed: Mar. 3, 2009
(86) PCT No.: PCT/JP2009/053992

§ 371 Date: Sep. 10, 2010

(30) Foreign Application Priority Data
Mar. 12, 2008 (JP) 2008-063291

(51) Int. Cl. H01L 27/092; H01L 29/78; H01L 21/30; H01L 29/739

(52) U.S. Cl. 257/369; 257/288; 257/412; 438/458; 257/E29.255; 257/E21.211; 257/E27.062

(57) ABSTRACT

The present invention provides a semiconductor device capable of improving subthreshold characteristics of a PMOS transistor that is included in a thinned base layer and bonded to another substrate, a production method of such a semiconductor device, and a display device. The semiconductor device of the present invention is a semiconductor device, including:
a substrate; and
a device part bonded to the substrate,
the device part including a base layer and a PMOS transistor,
the PMOS transistor including a first electrical conduction path and a first gate electrode,
the first electrical conduction path being provided inside the base layer on a side where the first gate electrode is disposed.

### TECHNICAL FIELD

The present invention relates to a semiconductor device, a production method thereof, and a display device. More particularly, the present invention relates to a semiconductor device suitably used in display devices such as a liquid crystal display device and an organic electroluminescent display device, and to a production method of such a semiconductor device, and a display device.

### BACKGROUND ART

Semiconductor devices are electronic devices including active elements utilizing electric characteristics of a semiconductor material. Such semiconductor devices have been widely used in audio equipment, communication equipment, computers, home electronics, and the like. Particularly, semiconductor devices including a three-terminal active elements such as a thin film transistor (hereinafter, also referred to as a “TFT”) and a MOS (metal oxide semiconductor) transistor are used as a pixel switching element that is arranged in each pixel, a pixel control circuit for controlling each pixel, and the like, in display devices such as an active matrix liquid crystal display device (hereinafter, also referred to as an “LC display”) and an organic electroluminescent display device (hereinafter, also referred to as an “organic EL display”).

There is known a SOI (silicon on insulator) substrate, which is a silicon substrate including a single crystal silicon layer formed on an insulating layer surface. By disposing a device such as a transistor on the SOI substrate, a decrease in parasitic capacitance and an increase in insulating resistance are provided. That is, devices can be provided with higher performance and/or higher integration degree. The above-mentioned insulating layer is composed of, for example, a silicon oxide (SiO₂) film.

In the SOI substrate, it is preferable that a thinner single crystal silicon layer is formed in order to increase a speed of operation of the device and to further decrease the parasitic capacitance. A variety of methods for forming the SOI substrate are known, and examples thereof include mechanical polishing, chemical mechanical polishing (CMP), and a method including use of porous silicon. The Smart-Cut process, which is one hydrogen implantation-involving method, has been proposed as disclosed in, for example, Non-Patent Documents 1 and 2. The Smart-Cut process includes: implanting hydrogen into a semiconductor substrate; bonding the substrate to another substrate; and separating the semiconductor substrate along the hydrogen-implanted layer by a thermal treatment, whereby transfer of the device is completed.

This technology can provide a SOI substrate that is a silicon substrate including a single crystal silicon layer formed on an insulating layer surface. When a device such as a transistor is formed on this SOI substrate structure, a reduction in parasitic capacitance and an increase in insulating resistance are permitted, and as a result, the device can be provided with high performance and/or high integration degree.

There is disclosed in Patent Document 1 a technology of ensuring formation of a separation layer in a base layer and allowing easy control of ion implantation of a substance for separation. According to this technology, an insulating film for element isolation or a LOCOS oxide film is formed so that its surface is positioned at the same height as that of a film covering an active region of a base layer in a first region, and then, a separation layer is formed in the base layer.

### [Non-Patent Document 1]

M. Bruel (1995), “Silicon on insulator material technology”, Electronics Letters, vol. 31, No. 14, p. 1201 to 1202, U.S.

### [Non-Patent Document 2]

Michel Bruel, and three others (1997), “Smart-cut: A New Silicon On Insulator Material Technology Based on Hydrogen Implantation and Wafer Bonding,” Japanese Journal of Applied Physics, vol. 36, No. 3B, p. 1636 to 1641, Japan.

### [Non-Patent Document 3]

Yuan Taur and Tak H. Ning, translated by Shibahara Kentaro, and five others (2002), “Taur-Ning, Fundamentals of Modern VLSI Devices”, Maruzen Co., Ltd., p. 261 to 263.

### [Patent Document 1]

Japanese Kokai Publication No. 2006-66591

### DISCLOSURE OF INVENTION

The present inventors found the base film can be thinned in the following manner: A device part including an element such as a MOS transistor is formed in abase layer; and into the base layer, a separation layer is formed; the device part is bonded to another substrate; and part of the base layer is separated and removed along the separation layer. Further, by utilizing this way, a device part including an element such as a MOS transistor, can be produced by being thinned. Further, when the another substrate to which the device part is to be bonded is a transparent substrate, a semiconductor device including the thinned base layer is applicable to display devices such as an LCD device and an organic EL display.

As a result of the inventors' diligent studies, evaluation of electric characteristics of a NMOS transistor and a PMOS transistor, each of which is formed in a thinned base layer and bonded to another substrate, yielded the following results: the NMOS transistor shows excellent characteristics, and on the other hand, as for the PMOS transistor, the subthreshold characteristics (subthreshold slope) are possibly deteriorated.

Referring to FIG. 25, the following will mention results of a measurement made by the present inventors. FIG. 25 is a graph showing operation characteristics of conventional NMOS and PMOS transistors that are included in a thinned single crystal silicon layer and bonded to another substrate. FIG. 25 shows results under the condition of W (channel width)/L (channel length)=10 μm/10 μm. As shown in FIG. 25, it is shown that subthreshold characteristics of the PMOS transistor got worsen markedly when the single crystal silicon layer has a small thickness.

The present invention is devised considering the aforementioned situations. An object of the present invention is to provide a semiconductor device capable of improving subthreshold characteristics of a PMOS transistor that is included in a thinned base layer and that is bonded to another substrate, and also provide a production method thereof and a display device.

The present inventors made various investigations on a semiconductor device capable of improving subthreshold characteristics of a PMOS transistor that is included in a thinned base layer and that is bonded to another substrate, a production method thereof, and a display device. The inventors noted a location of an electrical conduction path (hereinafter, also referred to as a channel) of the PMOS transistor.

The present inventors studied on a factor of the deterioration of the subthreshold characteristics of the PMOS transistor that is included in a thinned base layer and bonded to another substrate, and then found the followings. The gate electrode of the PMOS transistor usually employs an N⁺ polysilicon gate, as disclosed in Non-patent Document 3. Generally, when an N⁺ polysilicon gate is used as the gate electrode, as disclosed in Non-patent document 3, it is known that an NMOS transistor is made as a surface channel MOS transistor and a PMOS transistor is made as a buried channel MOS transistor such that a threshold voltage of each transistor is properly set because the gate electrode and each of the NMOS and PMOS transistors are different in work function or in impurity concentration distribution in the channel region.

The PMOS transistor that is included in a thinned base layer and bonded to another substrate is formed through separation of part of the base layer along the separation layer. Therefore, the base layer probably has a surface with large irregularities on the side opposite to the gate electrode, i.e., on the separation layer side, and further, etching damages attributed to the thinning for the base layer would remain on the surface.

FIG. 26 is a cross-sectional view schematically showing a conventional MOS transistor that is included in a thinned base layer and bonded to another substrate. FIG. 26(a) shows an NMOS transistor, and FIG. 26(b) shows a PMOS transistor. As shown in FIG. 26(a), an NMOS transistor 100 includes a source-drain region 104, a P-well region 108, and a channel 105. The source-drain region 104 and the P-well region 108 are formed in the base layer 103. The channel 105 is provided inside the base layer 103 on a side where the gate electrode 101 is disposed (near the gate insulating film 102 in the P-well region 108). Thus, the NMOS transistor 100 is a surface channel MOS transistor. Therefore, the channel 105 is hardly affected by the base layer 103 surface on the side opposite to the gate electrode 101. On the other hand, as shown in FIG. 26(b), the PMOS transistor 110 is a buried channel MOS transistor. That is, in the PMOS transistor 110, a channel 115 is formed in a somewhat deeper position than the boundary between a gate insulating film 112 and an N-well region 107 (a region between source-drain regions 114), thereby making the potential for holes minimized. Therefore, when the thickness of the base layer 113 is equivalent to or smaller than a depth at which the channel 115 is formed, the channel 115 would be affected by irregularities on the base layer 113 surface on the side opposite to the gate electrode 111 and/or by etching damages attributed to the thinning of the base layer 113. As a result, the subthreshold characteristics of the PMOS transistor 110 would be deteriorated.

After further studies, the inventors found that the subthreshold characteristics of the PMOS transistor can be improved as follows. When the PMOS transistor that is included in a thinned base layer and bonded to another substrate is made as a surface channel MOS transistor, specifically when a channel of the PMOS transistor is provided inside a base layer on a side where a gate electrode of the PMOS transistor is disposed, even in such a PMOS transistor, which is formed in the thinned base layer and bonded to another substrate, its channel is not affected by irregularities of the base layer surface on the side opposite to the gate electrode and/or by etching damages attributed to the thinning for the base layer. As a result, the above-mentioned problems have been admirably solved, leading to completion of the present invention.

A first aspect of the present invention provides a semiconductor device, including:

a substrate; and

a device part bonded to the substrate,

the device part including a base layer and a PMOS transistor,

the PMOS transistor including a first electrical conduction path and a first gate electrode,

the first electrical conduction path being provided inside the base layer on a side where the first gate electrode is disposed.

According to the first aspect of the present invention, the base layer includes the first electrical conduction path (a channel of the PMOS transistor) on the first gate electrode (a gate electrode of the PMOS transistor) side. Specifically, the PMOS transistor is a surface channel MOS transistor. According to this, even if the base layer is thinned, the channel of the PMOS transistor is not affected by irregularities of the base layer surface on the side opposite to the gate electrode and/or by etching damages attributed to the thinning of the base layer. As a result, it becomes possible to provide a PMOS transistor having excellent subthreshold characteristics.

In the PMOS transistor, a gate insulating film is usually disposed between the gate electrode and the base layer. Accordingly, it can be also said that the electrical conduction path of the PMOS transistor in the semiconductor device of the present invention is provided inside the base layer on a side where the base insulating film is disposed.

In the present description, the electrical conduction path (channel) means a region into which a current flows when a voltage is applied between a source region and a drain region (an inversion layer located between the source region and the drain region). According to calculation based on the quantum effect model, a channel is known to have a certain breadth and have a peak position (position with the highest electron or hole concentration) about 2 nm away from a gate insulating film/base layer interface. It is also known that at the gate insulating film/base layer interface, the existence probability of electrons or holes is zero. Therefore, it is sufficient that the channel of the PMOS transistor is located 0.1 nm to 5 nm away from the gate insulating film/base layer interface, like in common surface channel MOS transistors.

The device part is a part constituted by one or more elements formed in the base layer. The number of the element included in the device part is not especially limited, and may be one or several millions or more. That is, the device part may be an integrated circuit, and also may be a so-called integrated circuit chip. The device part also may be a large scale integration (LSI) circuit.

The element included in the above-mentioned device part is not especially limited, and elements other than the above-mentioned PMOS and NMOS transistors may be included. Examples of the other elements include a diode, a resistance, a bipolar transistor, a capacitor, and an inductance.

Thus, according to the present invention, the subthreshold characteristics of the PMOS transistor that is included in the thinned base layer and bonded to another substrate can be improved. Therefore, the device part that includes the PMOS transistor and is bonded to the substrate can be provided with higher performances. Accordingly, a part with a high integration degree (e.g., memory, CPU, a fine transistor such as a circuit control) is formed on the device part, whereby the device part can be made into an integrated circuit or a LSI. Further, a large-sized electric element such as a large-area capacitor or inductor can be formed on the substrate. Thus, an optimal design of a semiconductor device which operates only after being finally integrated on a substrate becomes possible. As a result, such a semiconductor device can be produced with high yield and productivity.

A second aspect of the present invention provides a semiconductor device, including:

a substrate; and

a device part bonded to the substrate,

the device part including a base layer and a PMOS transistor,

the PMOS transistor being a surface channel MOS transistor.

Also by the semiconductor device according to the second aspect of the present invention, the same effect as in the semiconductor device according to the first aspect of the present invention can be exhibited. Hereinafter, the phrase “semiconductor device of the present invention” means both of the semiconductor devices according to the first and second aspects of the present invention.

The configuration of the semiconductor device of the present invention is not especially limited. The semiconductor device may or may not include other components as long as it essentially includes the above-mentioned components.

The following will mention preferable embodiments of the semiconductor device of the present invention in detail. The following various embodiments may be used in a proper combination.

It is preferable that the base layer is formed by separating and removing part of the base layer along a separation layer that contains a substance used for the separation. According to this, the thinning of the base layer leads to an increase in operation speed of the device part and a decrease in parasitic capacitance. When the base layer is thinned in this manner, however, the base layer surface is provided with irregularities, as mentioned above. Therefore, in a conventional PMOS transistor, which is a buried channel MOS transistor, its subthreshold characteristics are possibly deteriorated. In contrast to this, the present invention allows effectively suppressing the deterioration of the subthreshold characteristics of the PMOS transistor.

It is preferable that the base layer is formed by further being thinned after the separation and removal. According to this, the thickness of the base layer can be set to a proper value that allows desired characteristics of the element such as the PMOS transistor included in the device part. The thickness of the base layer is closely related to the characteristics (threshold voltage, short channel effect, and the like) of the MOS transistor. The finer the MOS transistor becomes, the thinner the base layer becomes. The thickness of the base layer is required to be properly set in order to obtain desired characteristics of the MOS transistor.

It is preferable that the substance used for the separation contains at least one of hydrogen and an inert element. According to this, part of the base layer including the separation layer formed therein can be easily separated and removed. The substance used for the separation may contain hydrogen or an inert element singly or a combination thereof.

The method of forming the above-mentioned PMOS transistor as a surface channel MOS transistor is not especially limited. Suitably used is a method of making a P⁺ polysilicon gate as the gate electrode (the first gate electrode) of the PMOS transistor, as disclosed in Non-Patent Document 3, for example. Specifically, it is preferable that the first gate electrode contains P-type conductive polysilicon. According to this method, a state of a hole energy band in the PMOS transistor becomes completely the same as a state of an electron energy band in the NMOS transistor by inverting its polarity. Therefore, like the NMOS transistor, the PMOS transistor also operates as a surface channel one. Thus, the material of the first gate electrode is not limited to metal.

When the first gate electrode contains P-type conductive polysilicon, it is preferred that the first gate electrode contains a P-type impurity element. According to this, the P-type conductive polysilicon can be made into P⁺ polysilicon, which allows easily making the surface channel PMOS transistor.

It is preferable that the P-type impurity element includes boron. According to this, the surface channel PMOS transistor can be easily made.

It is preferable that the concentration of the P-type impurity element is 1×10¹⁹ to 1×10²² cm⁻³. According to this, the location of the channel of the PMOS transistor can be preferably controlled to a region near the base layer surface on the first gate electrode side.

The substrate is not especially limited as long as the device part can be bonded thereto. It is preferable that the substrate is a glass substrate or a single crystal silicon substrate. When a glass substrate is used as the substrate, the substrate is a transparent one, so that it becomes possible to apply the semiconductor device of the present invention to a display device such as an LCD device.

The base layer is not especially limited as long as it is a layer into which the element can be formed. It is preferable that the base layer is a layer containing a highly crystalline semiconductor such as single crystal silicon and polycrystal silicon. More specifically, it is preferable that the base layer contains at least one semiconductor selected from the group consisting of single crystal silicon semiconductors, Group IV semiconductors, Group II-VI compound semiconductors, Group III-V compound semiconductors, Group IV-IV compound semiconductors, mixed crystals thereof, and oxide semiconductors. As a result, the semiconductor device of the present invention is suitably applicable to optical devices such as a light-emitting diode, a photodiode, and a solid-state laser, or high-speed or high temperature devices.

The semiconductor device may further include, in addition to the device part, a conductive layer and an electric element each formed on the substrate,

wherein the PMOS transistor is electrically connected to the electric element through the conductive layer. As a result, the device part including the PMOS transistor can control an electric element, so that when the electric element is a pixel switching element, the semiconductor device of the present invention is preferably applicable to LC displays (so-called monolithic LC display) including a pixel part and a peripheral driver circuit integrated therewith such as a driving circuit and a control circuit.

It is preferable that the device part further includes an NMOS transistor,

the NMOS transistor includes a second electrical conduction path and a second gate electrode, and

the second electrical conduction path is provided inside the base layer on a side where the second gate electrode is disposed.

As a result, a surface channel MOS transistor can be made as each of the PMOS and NMOS transistors, and therefore a CMOS transistor excellent in subthreshold characteristics can be formed in the device part. In the present description, the second gate electrode means a gate electrode of the NMOS transistor; and the second electrical conduction path means an electrical conduction path of the NMOS transistor.

Like in the above-mentioned PMOS transistor, the method of making a surface channel MOS transistor as the NMOS transistor is not especially limited. Suitably used is a method of making an N⁺ polysilicon gate as the gate electrode (the second gate electrode) of the NMOS transistor, as disclosed in Non-Patent Document 3, for example. Specifically, it is preferable that the second gate electrode contains N-type conductive polysilicon. Thus, the material of the second gate electrode is not limited to metal.

When the second gate electrode contains N-type conductive polysilicon, it is preferred that the second gate electrode contains an N-type impurity element. According to this, the N-type conductive polysilicon can be made into N⁺ polysilicon, which allows easily making a surface channel NMOS transistor.

It is preferable that the N-type impurity element includes at least one of phosphorus and arsenic. According to this, a surface channel NMOS transistor can be easily made. The N-type impurity element may contain phosphorus or arsenic singly or a combination thereof.

It is preferable that the concentration of the N-type impurity element is 1×10¹⁹ to 1×10²² cm⁻³. According to this, the location of the channel of the NMOS transistor can be preferably controlled to a region near the base layer surface on the second gate electrode side.

The semiconductor device may further include, in addition to the device part, a conductive layer and an electric element each formed on the substrate,

wherein the PMOS transistor and the NMOS transistor may be electrically connected to the electric element through the conductive layer. According to this, the PMOS and NMOS transistors can constitute a CMOS transistor, so that the device part with a high integration degree and/or low power consumption can control the electric element.

Another aspect of the present invention provides a method of producing the semiconductor device of the present invention,

the method including:

a separation layer-forming step that includes forming the

MOS transistor, and then forming a separation layer in part of the base layer, the separation layer containing a substance used for the separation;

a bonding step that includes bonding the substrate to the device part after the separation layer-forming step; and

a separation and removal step that includes separating and removing part of the base layer along the separation layer after the bonding step. This production method allows easy production of the semiconductor device of the present invention.

The production method of the semiconductor device of the present invention is not especially limited, and may or may not include other steps as long as it essentially includes the above-mentioned steps.

The method of separating and removing part of the base layer is not especially limited, but a heating treatment can be preferably used, for example. That is, it is preferable that the separation and removal step includes a heating treatment. According to this, part of the base layer including the separation layer formed therein can be easily separated and removed.

It is preferable that the method of producing the semiconductor device further includes a step of further thinning the base layer after the separation and removal step. According to this, the thickness of the base layer can be set to a proper value that allows desired characteristics of the PMOS transistor included in the device part.

Yet another aspect of the present invention provides a display device including the semiconductor device of the present invention or a semiconductor device produced by the production method of present invention. According to this, the semiconductor device including a highly integrated device part excellent in transistor characteristics can be mounted on a display device, so that the display device can be provided with a thin profile, a narrow frame region, and high performances.

### Effect of the Invention

The semiconductor device, the production method thereof, and the display device of the present invention can improve subthreshold characteristics of a PMOS transistor that is included in a thinned base layer and bonded to another substrate.

### BEST MODES FOR CARRYING OUT THE INVENTION

Referring to drawings, the present invention is mentioned in more detail below by means of Embodiments, but not limited only to these Embodiments.

### Embodiment 1

The following will mention a configuration of a semiconductor device of Embodiment 1 with reference to the drawings. FIG. 1 is a cross-sectional view schematically showing a structure of the semiconductor device of Embodiment 1. FIG. 1 shows only two transistors, one NMOS transistor, and the other PMOS transistor, but the element formed in the device part is not limited thereto, and a variety of semiconductor elements can be used. The number of the element included in the device part is not limited. The device part may include one, or several millions or more elements.

As shown in FIG. 1, a semiconductor device 70 of the present Embodiment includes: a glass substrate 38; a device part 60 bonded to the glass substrate 38; and electric elements 42 that are an active or passive element formed on the glass substrate 38. The glass substrate 38, the device part 60, and the electric element 42 are covered by a protective film 39. An NMOS transistor 50n and a PMOS transistor 50p in the device part 60 are electrically connected to the electric elements 42 by metal wirings (conductive layers) 41 through contact holes 40, respectively.

The device part 60 includes: a silicon layer (silicon substrate, base layer) 1; the NMOS transistor 50n; the PMOS transistor 50p; a flattening layer 37; an interlayer insulating film 34; a flattening layer 31; and a metal wiring 36. The NMOS transistor 50n and the PMOS transistor 50p are formed in the silicon layer 1, and are isolated from each other by a LOCOS oxide film 10. The flattening layer 37, the interlayer insulating film 34, and the flattening layer 31 are stacked in this order from the glass substrate 38 to the silicon layer 1.

The PMOS transistor 50p includes an active region 13a, a P-type lightly-doped region 23, a P-type heavily-doped region 30, a gate oxide film (gate insulating film) 16, and a gate electrode 17p (a first gate electrode). The P-type lightly-doped region 23, the P-type heavily-doped region 30, and the gate oxide film 16 are included in the silicon layer 1. The gate electrode 17p faces the silicon layer 1 with the gate oxide film 16 therebetween. The P-type heavily-doped region 30 is connected to the metal wiring (conductive layer) 41 by the metal electrode 36 through the contact hole 35.

The NMOS transistor 50n includes an active region 13b, an N-type lightly-doped region 20, an N-type heavily-doped region 27, a gate oxide film 16, and a gate electrode 17n (a second gate electrode). The active region 13b, the N-type lightly-doped region 20, the N-type heavily-doped region 27, and the gate oxide film 16 are included in the silicon layer 1. The gate electrode 17n faces the silicon layer 1 with the gate oxide film 16 therebetween. The N-type heavily-doped region 27 is connected to the metal wiring (conductive layer) 41 by the metal electrode 36 through the contact hole 35.

The gate electrode 17p is composed of P⁺ polysilicon and on the other hand, the gate electrode 17n is composed of N⁺ polysilicon. Thereby, the PMOS transistor 50p and the NMOS transistor 50n can be made into surface channel MOS transistors. Specifically, the silicon layer 1 includes a channel (the first electrical conduction path) of the PMOS transistor 50p and a channel (the second electrical conduction path) of the NMOS transistor 50n on the side where the gate electrodes 17p and 17n (the gate oxide film 16) are arranged. More specifically, the channel of the PMOS transistor 50p and the channel of the NMOS transistor 50n are each formed near the silicon layer 1 surface on the gate electrodes 17p and 17n (the gate oxide film 16) side (in a region 0.1 nm to 5 nm away from the interface between the gate oxide film 16 and the silicon layer 1). According to this, the channel of the PMOS transistor 50p and the channel of the NMOS transistor 50n are not affected by irregularities of the silicon layer 1 surface on the side opposite to the gate electrodes 17p and 17n and/or by etching damages attributed to a thinning step for the silicon layer 1. As a result, the PMOS transistor 50p and NMOS transistor 50n can both exhibit excellent subthreshold characteristics.

The following will mention a method of the semiconductor device of the present Embodiment. FIGS. 2 to 23 are cross-sectional views each schematically showing a production step of the semiconductor device of Embodiment 1.

First, as shown in FIG. 2, a thermal oxide film 2 with about 30 nm in thickness is formed on a silicon substrate (base layer) 1. The thermal oxide film 2 is formed for the purpose of preventing contamination of the silicon substrate surface in an ion implantation step. Preferably, although not necessarily, the thermal oxide film 2 is formed.

Then, as shown in FIG. 3, using a resist 3 as a mask, an N-type impurity element 4 is ion-implanted into a region free from the resist 3, which is a region to become an N-well region. Phosphorus can be used, for example, as the N-type impurity element 4. The ion implantation is performed under the following conditions: the implantation energy is about 50 to 150 keV; the dose amount is about 1×10¹² to 5×10¹³ cm⁻². In this case, when a P-type impurity element is implanted into the entire main surface of the silicon substrate 1 in a next step, the dose amount of the N-type impurity element is increased in consideration of that to be compensated by the P-type impurity element.

Next, as shown in FIG. 4, the resist 3 is removed and then, a P-type impurity element 5 is ion-implanted into the entire main surface of the silicon substrate 1. Boron can be used, for example, as the P-type impurity element 5. The ion implantation is performed under the following conditions: the implantation energy is about 10 to 50 keV; the dose amount is about 1×10¹² to 5×10¹³ cm⁻². The thermal diffusion coefficient of phosphorus in silicon is smaller than that of boron, so that phosphorus may be previously diffused by a thermal treatment prior to the boron implantation, thereby appropriately diffusing phosphorus into the silicon substrate 1. In order to prevent the N-type impurity element 4 from being compensated by the P-type impurity element 5 in a region where an N-well region 7 is to be formed in a next step, the implantation of the P-type impurity element 5 may be performed after a resist is formed on the region where the N-well region 7 is to be formed in a next step. In this case, the implantation of the N-type impurity element 4 for forming the N-well region 7 may be performed without consideration of the compensation by the P-type impurity element 5.

Then, as shown in FIG. 5, the thermal oxide film 2 is removed, and then, a thermal treatment is carried out at about 900° C. to 1000° C. in oxidizing atmosphere. As a result, a thermal oxide film 6 with about 30 nm in thickness is formed, and the impurity element having been implanted into the silicon substrate 1 in the above-mentioned step is diffused, and thus, the N-well region 7 and a P-well region 8 are formed.

Then, as shown in FIG. 6, a silicon nitride film 9 with about 200 nm in thickness is formed by CVD and the like, and then, the silicon nitride film 9 and the thermal oxide film 6 are patterned.

Then, as shown in FIG. 7, a thermal treatment for LOCOS oxidation is carried out at about 900° C. to 1000° C. in oxygen atmosphere, and thereby a LOCOS oxide film 10 with about 200 to 500 nm in thick is formed. The LOCOS oxide film 10 is a film for element isolation. The element isolation can be achieved by methods other than the LOCOS oxidation, such as STI (shallow trench isolation).

Then, as shown in FIG. 8, the silicon nitride film 9 and the thermal oxide film 6 are once removed, and then a thermal treatment is carried out at about 1000° C. in oxygen atmosphere, and thereby a thermal oxide film 11 with about 20 nm in thickness is formed.

Then, as shown in FIG. 9, a resist 12 is formed such that it does not cover a region where the PMOS is to be formed. Further, an impurity element 13 for setting a threshold voltage of the PMOS transistor is ion-implanted into the N-well region 7. In this case, in order to adjust the threshold voltage of the P⁺ polysilicon gate to a desired value, phosphorus, which is an N-type impurity element, is ion-implanted into the channel of the PMOS transistor at 10 to 50 keV and in a dose amount of about 1×10¹² to 5×10¹³ cm⁻².

Then, as shown in FIG. 10, a resist 14 is formed such that it does not cover the NMOS transistor region. Further, an impurity element 15 for setting a threshold voltage of the NMOS transistor is ion-implanted into the P-well region 8. In this case, in order to adjust the threshold voltage of the N⁺ polysilicon gate to a desired value, boron, which is a P-type impurity element, is ion-implanted into the channel of the NMOS transistor at an implantation energy of about 10 to 50 keV and in a dose amount of about 1×10¹² to 5×10¹³ cm⁻². The relationship between the threshold value and the channel dose amount varies depending on the material and the conductive-type of the gate electrode, and conditions of the subsequent thermal treatment. Therefore, the channel dose amount is required to be set according to the respective process conditions.

Then, as shown in FIG. 11, the resist 14 and the thermal oxide film 11 are once removed, and then, a heat treatment is carried out at about 1000° C. in oxygen atmosphere, and thereby a gate oxide film (gate insulating film) 16 with about 10 to 20 nm in thickness is formed. At this time, the impurity elements 13 and 15 having been implanted in the above-mentioned steps are diffused to form active regions 13a and 15a, respectively.

Then, as shown in FIG. 12, a gate electrode 17n of the NMOS transistor and a gate electrode 17p of the PMOS transistor are formed. The gate electrodes 17n and 17p are formed by depositing polysilicon about 300 nm in thickness by CVD and the like and then patterning the deposited polysilicon.

Then, as shown in FIG. 13, a resist 18 is formed such that it does not cover the NMOS transistor region. Using the gate electrode 17n as a mask, an N-type impurity element 19 such as phosphorus is ion-implanted into the NMOS transistor region, thereby forming an N-type lightly-doped region 20. When phosphorus is used as the N-type impurity element 19, the ion implantation is performed under the following conditions: the implantation energy is about 10 to 50 keV, and the dose amount is about 1×10¹³ to 2×10¹⁴ cm⁻². Arsenic may be used as the N-type impurity element 19 when the NMOS transistor has a short gate length and the N-type impurity element 19 is required to be implanted quite shallowly on the channel surface. In order to inhibit the short channel effect, a P-type impurity (for example, boron) may be implanted from an oblique direction if needed. The channel width of the NMOS transistor may be less than 1 μm, but is generally about 1 μm to 100 μm. The channel length of the NMOS transistor may be less than 0.1 μm, but is generally about 0.1 to 10 μm.

Then, as shown in FIG. 14, a resist 21 is formed such that it does not cover the PMOS transistor region. A P-type impurity element 22 such as boron is ion-implanted into the PMOS transistor region using the gate electrode 17p as a mask, thereby forming a P-type lightly-doped region 23. When boron is used as the p-type impurity element 22, the ion implantation is performed under the conditions: ⁴⁹BF₂⁺ is used as the boron; the implantation energy is about 10 to 50 keV; and the dose amount is about 1×10¹³ to 1×10¹⁴ cm⁻². The implantation of the P-type impurity element 22 into the PMOS transistor region may not be necessarily performed when thermal diffusion of a P-type impurity element 29 such as boron, which is to be heavily-doped in the PMOS transistor region in a next step for forming a P-type heavily-doped region 30, is enough for formation of the P-type lightly-doped region 23. The channel width of the PMOS transistor may be less than 1 μm, but is generally about 1 to 100 μm. The channel length of the PMOS transistor may be less than 0.1 μm, but is generally about 0.1 to 10 μm.

Then, as shown in FIG. 15, a SiO₂ film is formed by CVD and the like, and then by anisotropic dry etching, a side wall 24 of the SiO₂ film is formed on the both side walls of each of the gate electrodes 17n and 17p.

Then, as shown in FIG. 16, a resist 25 is formed such that it does not cover the NMOS transistor region. Using the gate electrode 17n and the side walls 24 as a mask, an N-type impurity element 26 such as phosphorus and arsenic is ion-implanted into the NMOS transistor region, thereby forming an N-type heavily-doped region 27. When arsenic is used for the ion implantation, the implantation is performed at about 20 to 80 keV and in a dose amount of about 1 to 3×10¹⁵ cm⁻². At this time, the N-type impurity element 26 is simultaneously implanted also into the polysilicon gate, which is the gate electrode 17n of the NMOS transistor. The concentration of the N-type impurity element in the gate electrode 17n is preferably 1×10¹⁹ to 1×10²² cm⁻³. Through the subsequent thermal treatment step, the gate electrode 17n of the NMOS transistor is made into N⁺ polysilicon.

Then, as shown in FIG. 17, a resist 28 is formed such that it does not cover the PMOS transistor region. Using the gate electrode 17p and the side walls 24 as a mask, a P-type impurity element 29 such as boron is ion-implanted into the PMOS transistor region, thereby forming a P-type heavily-doped region 30. When boron is used for the ion implantation, for example, the ion implantation is performed under the conditions: ⁴⁹BF₂⁺ is used as the boron; the implantation energy is about 10 to 60 keV; and the dose amount is about 1 to 3×10¹⁵ cm⁻². At this time, the P-type impurity element 29 is simultaneously implanted also into the polysilicon gate, which is the gate electrode 17p of the PMOS transistor. The concentration of the P-type impurity element contained in the gate electrode 17p is preferably 1×10¹⁹ to 1×10²² cm⁻³. Then, a thermal treatment is carried out, thereby activating the ion-implanted impurity element. As the thermal treatment, a treatment at 900° C. is performed for 10 minutes, for example. As a result, the gate electrode 17n of the NMOS transistor is made into an N⁺ polysilicon gate, and the gate electrode 17p of the PMOS transistor is made into a P⁺ polysilicon gate.

Then, as shown in FIG. 18, an insulating film of SiO₂ and the like is formed to cover the gate electrodes 17n and 17p and the side walls 24, and then flattened by CMP and the like to give a flattening film 31 with about 600 nm in thickness.

Then, as shown in FIG. 19, a substance used for the separation 32 containing at least one of hydrogen and an inert element (e.g., He, Ne) is ion-implanted into the silicon substrate 1, thereby forming a separation layer 33 in the N-well region 7 and the P-well region 8. When hydrogen is used as the substance 32, the implantation is performed under the following conditions: the dose amount is about 2×10¹⁶ to 1×10¹⁷ cm⁻²; and the implantation energy is about 100 to 200 keV.

Then, as shown in FIG. 20, an interlayer insulating film 34 is formed; contact holes 35 are formed; and then, a metal electrode 36 is formed. The flattening film 31, which is formed before the ion implantation of the substance 32, is made thick, whereby the contact hole 35 and the metal electrode 36 may be formed without forming the interlayer insulating film 34.

Then, as shown in FIG. 21, an insulating film is deposited by CVD and the like, and the surface thereof is polished by CMP and the like to give a flattening film 37. The flattening film 37 surface is washed with SC1 and the like, and positioned with a glass substrate 38 which has been also washed with SC1 and the like, to be bonded to each other by self-bonding such as Van der Waals force and hydrogen bond, and the like.

Then, as shown in FIG. 22, a thermal treatment is carried out at about 400 to 600° C., thereby separating and removing part of the silicon substrate 1 along the separation layer 33. Thus, transfer of the thinned device part 60 including the NMOS transistor 50n and the PMOS transistor 50p onto the glass substrate 38 is completed.

Then, as shown in FIG. 23, the separation layer 33 is removed by etching and the like, and then, the silicon layer 1 is etched until the LOCOS oxide film 10 is exposed. As a result, the NMOS transistor 50n and PMOS transistor 50p, which are included in the device part 60, are isolated from each other, and simultaneously, the silicon layer 1 is further thinned. The step of etching the silicon layer 1 until the exposure of the LOCOS oxide film 10 is not necessarily performed. The step of removing the separation layer 33 by etching and the like is not necessarily performed, and the separation layer 33 may remain, but preferably removed. The thickness of the silicon layer 1 is just 10 to 100 nm. Then, a protective film 39 is formed in order to protect the exposed surface of the silicon layer 1 and ensure electric insulation.

Then, as shown in FIG. 1, a contact hole 40 is formed, and then, a metal wiring (conductive layer) 41 is formed, thereby establishing electric connection to the electric element 42, which is previously formed active or passive element on the glass substrate 38 before the substrate attachment. Thus, the semiconductor device 70 of the present Embodiment can be produced.

According to the present Embodiment, in the PMOS transistor 50p, the channel can be formed in the region with 0.1 nm or more and 5 nm or less distance from the silicon layer 1 surface on the gate electrode 17p side; and in the NMOS transistor 50n, the channel can be located in the region 0.1 nm or more and 5 nm or less away from the silicon layer 1 surface on the gate electrode 17n side. Specifically, a surface channel MOS transistor can be made as each of the PMOS transistor 50p and the NMOS transistor 50n.

FIG. 24 is a plan view schematically showing the device part of the semiconductor device of Embodiment 1. In FIG. 23, the cross-sectional view of the PMOS transistor is a view taken along line A-B of FIG. 24, and the cross-sectional view of the NMOS transistor is a view taken along line C-D of FIG. 24. That is, the semiconductor device of the present Embodiment has a CMOS configuration composed of the NMOS transistor 50n and the PMOS transistor 50p. Specifically, a metal wiring 36i to which an input voltage is to be applied is electrically connected to the gate electrode 17n and the gate electrode 17p via a contact part 35g. Drain regions of the NMOS transistor 50n and PMOS transistor 50p are electrically connected to a metal wiring 36o from which an output voltage is fed through contact parts 35o and 35q, respectively. A source region of the NMOS transistor 50n is electrically connected to a metal wiring 36n via a contact part 35n, and on the other hand, a source region of the PMOS transistor 50p is electrically connected to a metal wiring 36p via a contact part 35p.

In FIG. 24, the metal wirings 36o, 36n, and 36p correspond to the metal electrode 36 in FIG. 1. The contact parts 35n, 35p, 35o, and 35q correspond to the contact hole 35 in FIG. 1. The drain regions of the NMOS transistor 50n and the PMOS transistor 50p correspond to the N-type heavily-doped region 27 and the P-type heavily-doped region 30 in FIG. 1, respectively. The source regions of the NMOS transistor 50n and the PMOS transistor 50p correspond to the N-type heavily-doped region 27 and the P-type heavily-doped region 30 in FIG. 1, respectively. Also the metal wiring 36i is formed of a wiring layer corresponding to the metal electrode 36 in FIG. 1, and the contact part 35g is formed similarly to the contact hole 35 in FIG. 1.

Although the semiconductor device of Embodiment 1 has been explained in detail with reference to the drawings as mentioned above, the present invention is not limited thereto. Materials other than polysilicon, for example, a metal material may be used for the gate electrode. When a metal material is used for the gate electrode, metal materials each of which has a suitable work function are independently formed in the NMOS transistor and the PMOS transistor so that the NMOS transistor and the PMOS transistor each exhibit surface channel operation. Elemental metals, metal nitrides, alloys, silicide, and the like may be used as the metal material. More specifically, TaSiN, Ta, TaN, TaTi, HfSi, ErSi, ErGe, NiSi, and the like, maybe used for the gate electrode of the NMOS transistor, for example. On the other hand, for the gate electrode of the PMOS transistor, TiN, Ru, TaGe₂, PtSi, NiGe, PtGe, NiSi, and the like, may be used.

The present application claims priority to Patent Application No. 2008-063291 filed in Japan on Mar. 12, 2008 under the Paris Convention and provisions of national law in a designated State, the entire contents of which are hereby incorporated by reference.

### BRIEF DESCRIPTION OF DRAWINGS

FIG. 1 is a cross-sectional view schematically showing a structure of a semiconductor device of Embodiment 1.

FIG. 2 is a cross-sectional view schematically showing a production step of the semiconductor device of Embodiment 1 (formation of thermal oxide film).

FIG. 3 is a cross-sectional view schematically showing a production step of the semiconductor device of Embodiment 1 (ion implantation of N-type impurity element).

FIG. 4 is a cross-sectional view schematically showing a production step of the semiconductor device of Embodiment 1 (ion implantation of P-type impurity element).

FIG. 5 is a cross-sectional view schematically showing a production step of the semiconductor device of Embodiment 1 (formation of N-well region and P-well region).

FIG. 6 is a cross-sectional view schematically showing a production step of the semiconductor device of Embodiment 1 (formation of silicon nitride film).

FIG. 7 is a cross-sectional view schematically showing a production step of the semiconductor device of Embodiment 1 (formation of LOCOS oxide film).

FIG. 8 is a cross-sectional view schematically showing a production step of the semiconductor device of Embodiment 1 (formation of thermal oxide film).

FIG. 9 is a cross-sectional view schematically showing a production step of the semiconductor device of Embodiment 1 (Implantation into channel of PMOS transistor).

FIG. 10 is a cross-sectional view schematically showing a production step of the semiconductor device of Embodiment 1 (Implantation into channel of NMOS transistor).

FIG. 11 is a cross-sectional view schematically showing a production step of the semiconductor device of Embodiment 1 (Formation of gate oxide film).

FIG. 12 is a cross-sectional view schematically showing a production step of the semiconductor device of Embodiment 1 (Formation of gate electrode).

FIG. 13 is a cross-sectional view schematically showing a production step of the semiconductor device of Embodiment 1 (Formation of N-type lightly-doped region).

FIG. 14 is a cross-sectional view schematically showing a production step of the semiconductor device of Embodiment 1 (Formation of P-type lightly-doped region).

FIG. 15 is a cross-sectional view schematically showing a production step of the semiconductor device of Embodiment 1 (Formation of side wall).

FIG. 16 is a cross-sectional view schematically showing a production step of the semiconductor device of Embodiment 1 (Formation of N-type heavily-doped region).

FIG. 17 is a cross-sectional view schematically showing a production step of the semiconductor device of Embodiment 1 (Formation of P-type heavily-doped region).

FIG. 18 is a cross-sectional view schematically showing a production step of the semiconductor device of Embodiment 1 (Formation of flattening film).

FIG. 19 is a cross-sectional view schematically showing a production step of the semiconductor device of Embodiment 1 (Formation of separation layer).

FIG. 20 is a cross-sectional view schematically showing a production step of the semiconductor device of Embodiment 1 (Formation of interlayer insulating film, contact hole, and metal electrode).

FIG. 21 is a cross-sectional view schematically showing a production step of the semiconductor device of Embodiment 1 (Bonding to glass substrate)

FIG. 22 is a cross-sectional view schematically showing a production step of the semiconductor device of Embodiment 1 (Transfer of device part).

FIG. 23 is a cross-sectional view schematically showing a production step of the semiconductor device of Embodiment 1 (Element isolation).

FIG. 24 is a plan view schematically showing a device part of the semiconductor device of Embodiment 1.

FIG. 25 is a graph showing operation characteristics of conventional NMOS and PMOS transistors that are included in a thinned single crystal silicon layer and bonded to another substrate.

FIGS. 26(a) and 26(b) are cross-sectional views each schematically showing a conventional MOS transistor that is included in a thinned single crystal silicon layer and bonded to another substrate. FIG. 26(a) shows an NMOS transistor, and FIG. 26(b) shows a PMOS transistor.

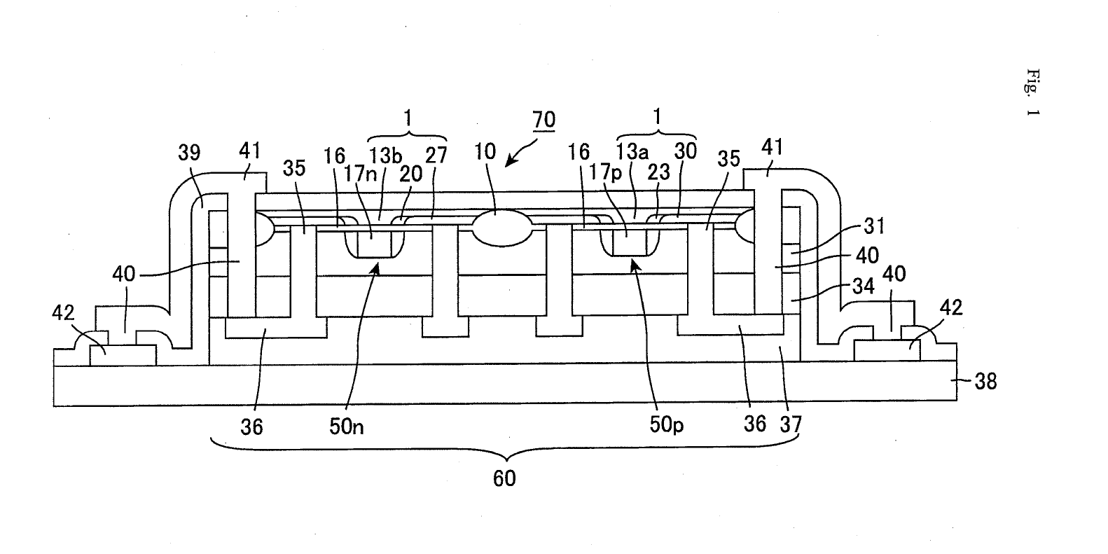

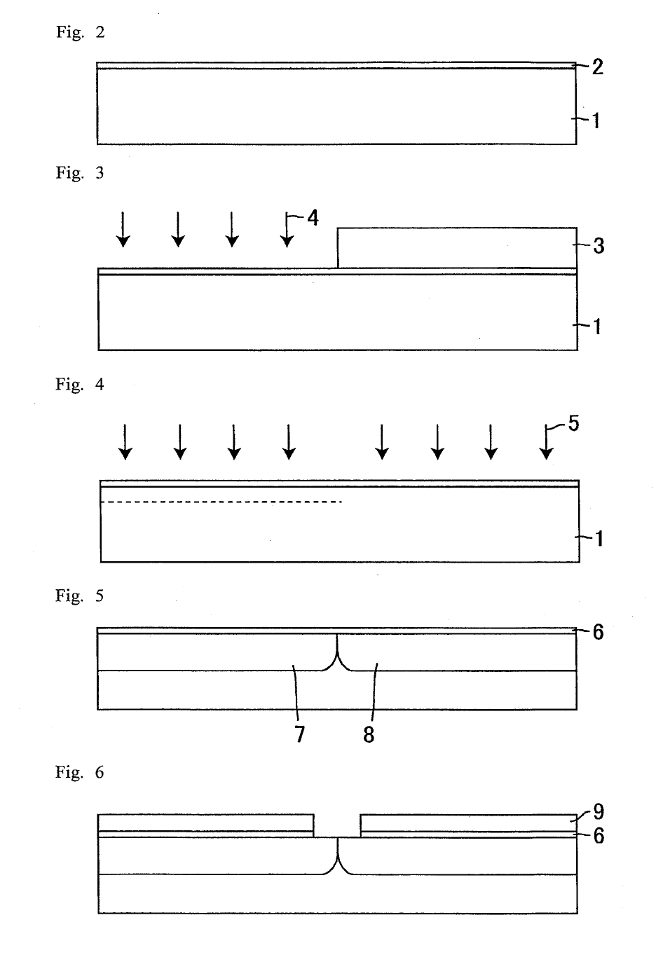

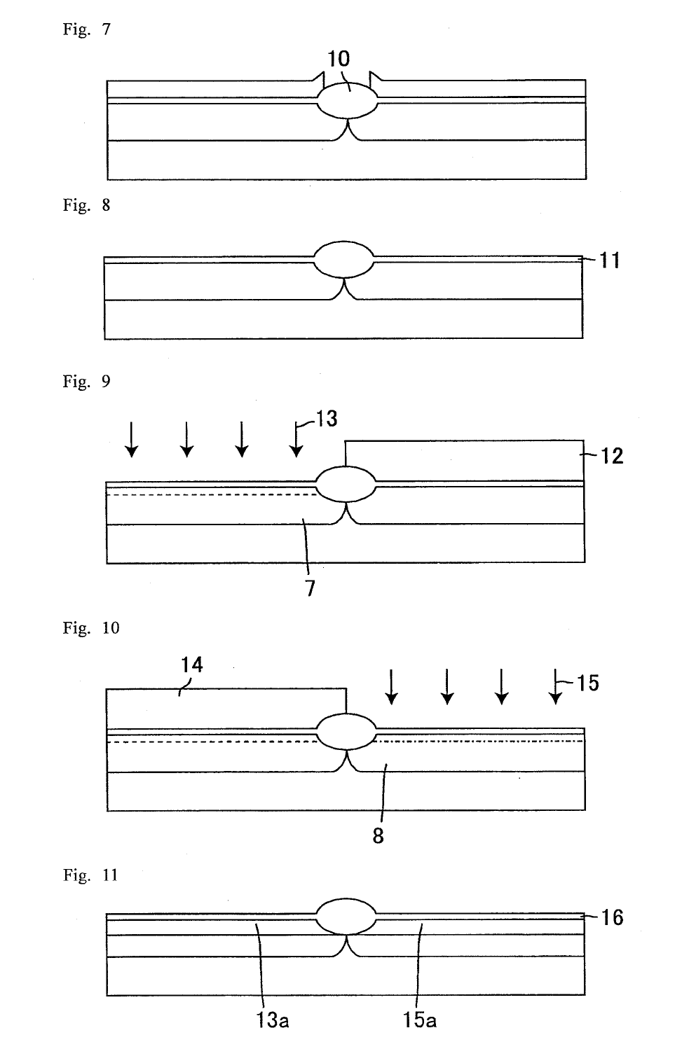

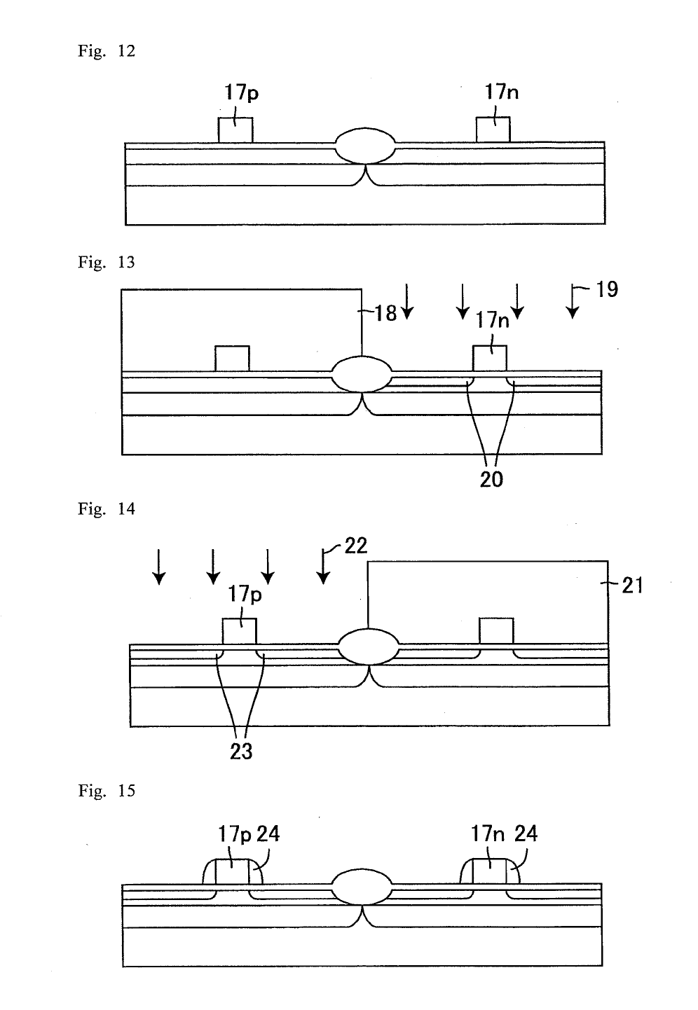

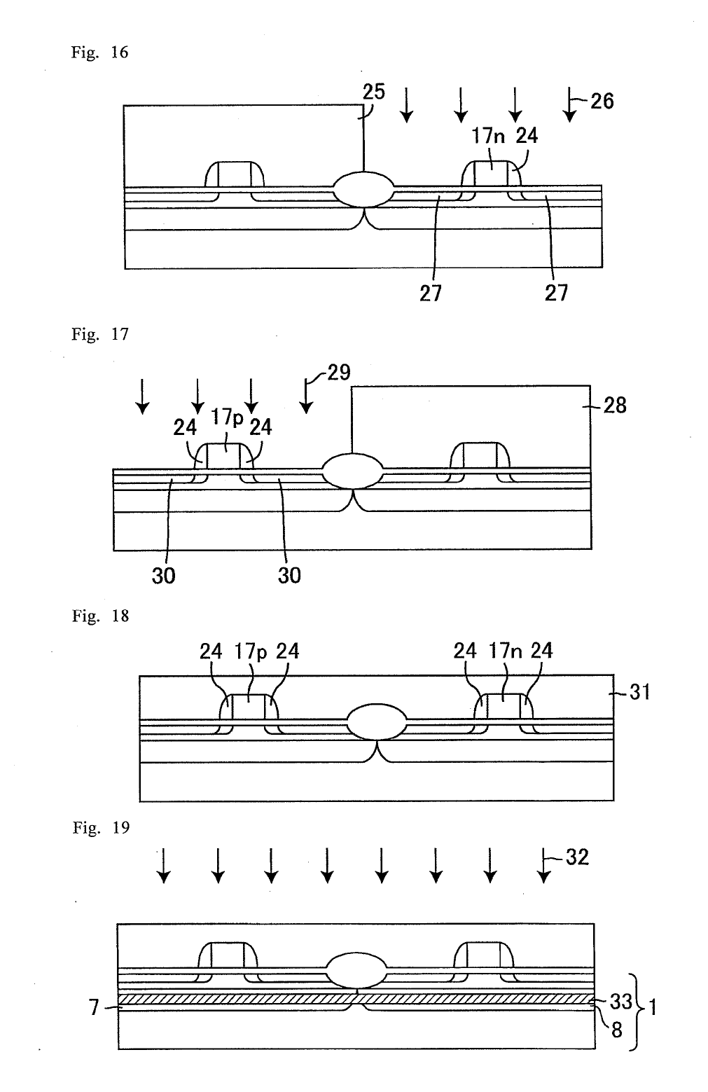

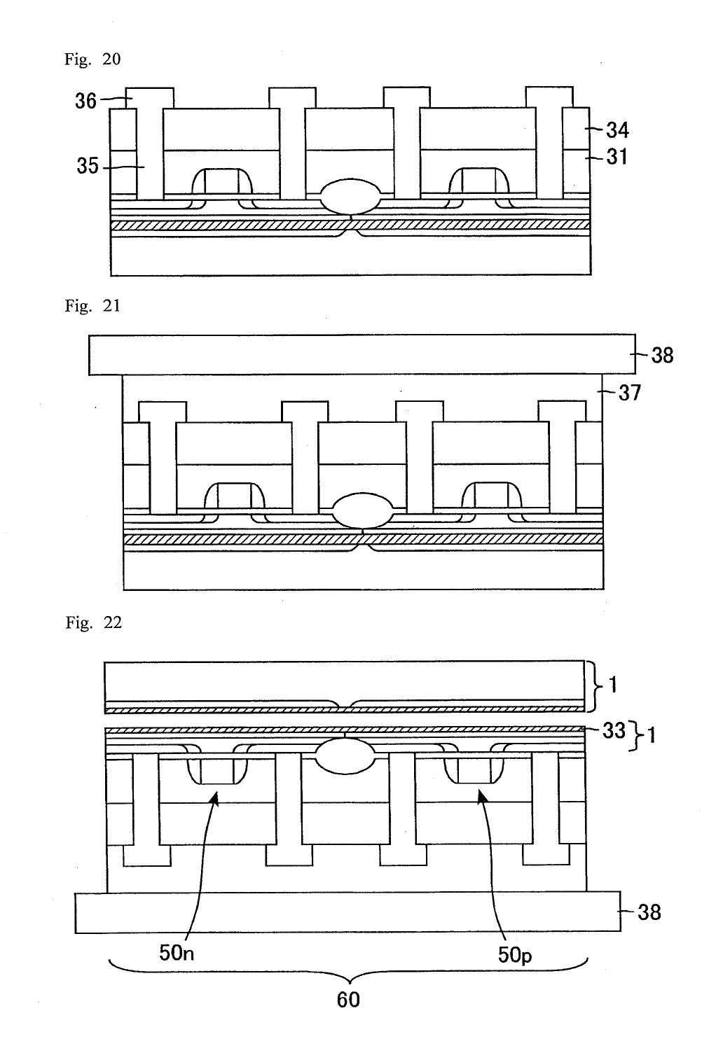

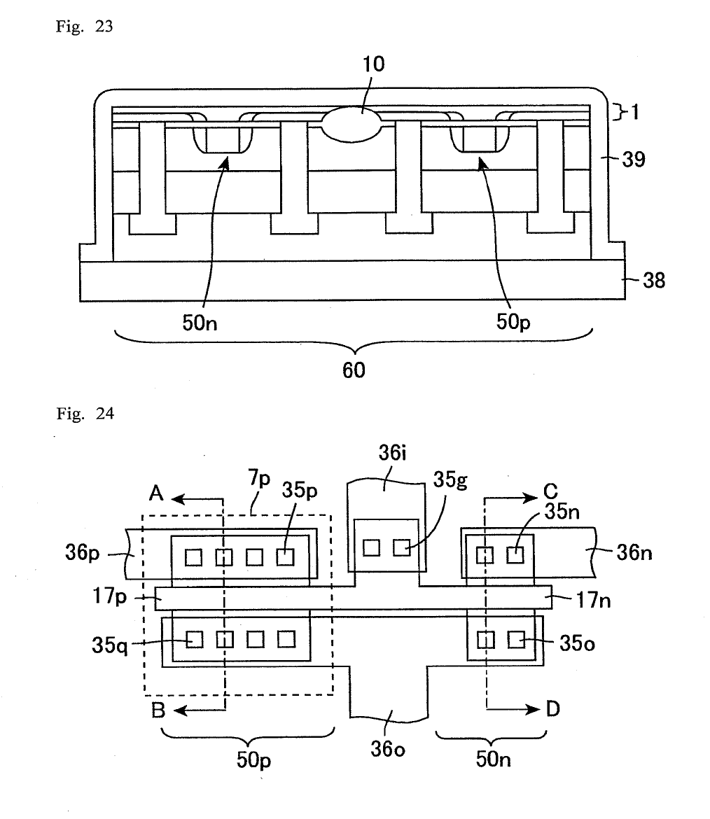

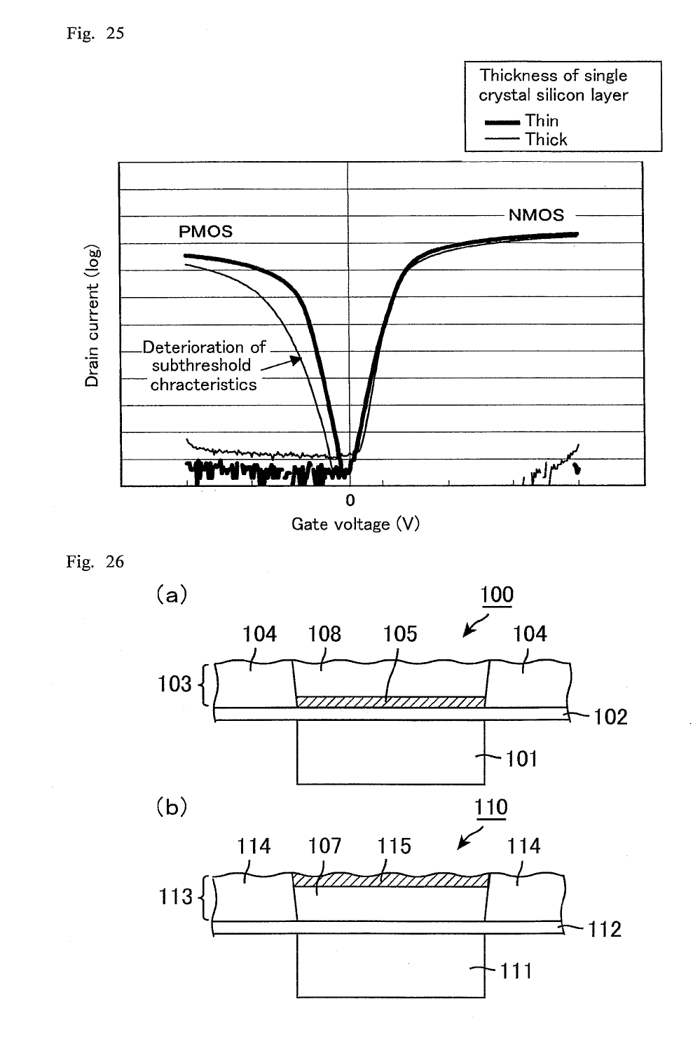

### EXPLANATION OF NUMERALS AND SYMBOLS

1, 103, 113: Silicon layer (silicon substrate, base layer)
2, 6, 11: Thermal oxide film
3, 12, 14, 18, 21, 25, 28: Resist
4: N-type impurity element
5: P-type impurity element
7, 107: N-well region
8, 108: P-well region
9: Silicon nitride film
10: LOCOS oxide film
13, 15: Impurity element
13a, 15a: Active region
16, 102, 112: Gate oxide film (gate insulating film)
17, 17n, 17p, 101, 111: Gate electrode
19, 26: N-type impurity element
20: N-type lightly-doped region
22, 29: P-type impurity element
23: P-type lightly-doped region
24: Side wall
27: N-type heavily-doped region
30: P-type heavily-doped region
31, 37: Flattening film
32: Substance used for separation
33: Separation layer
34: Interlayer insulating film
35, 40: Contact hole
35g, 35n, 35p, 35o, 35q: Contact part
36: Metal electrode
36i, 36o: Metal wiring
38: Glass substrate
39: Protective film
41: Metal wiring (conductive layer)
42: Electric element
50p, 110: PMOS transistor
50n, 100: NMOS transistor
60: Device part
70: Semiconductor device
104, 114: Source-drain region
105, 115: Channel

1. A semiconductor device, comprising:
a substrate; and
a device part bonded to the substrate,
the device part including a base layer and a PMOS transistor,
the PMOS transistor including a first electrical conduction path and a first gate electrode,
the first electrical conduction path being provided inside the base layer on a side where the first gate electrode is disposed.

2. The semiconductor device according to claim 1,
wherein the base layer is formed by separating and removing part of the base layer along a separation layer that contains a substance used for the separation.

3. The semiconductor device according to claim 2,
wherein the base layer is formed by further being thinned after the separation and removal.

4. The semiconductor device according to claim 2,
wherein the substance used for the separation contains at least one of hydrogen and an inert element.

5. The semiconductor device according to claim 1,
wherein the first gate electrode contains P-type conductive polysilicon.

6. The semiconductor device according to claim 5,
wherein the first gate electrode contains a P-type impurity element.

7. The semiconductor device according to claim 6,
wherein the P-type impurity element comprises boron.

8. The semiconductor device according to claim 6,
wherein the concentration of the P-type impurity element is 1×10¹⁹ to 1×10²² cm ⁻³.

9. The semiconductor device according to claim 1,
wherein the substrate is a glass substrate or a single crystal silicon substrate.

10. The semiconductor device according to claim 1,
wherein the base layer contains at least one semiconductor selected from the group consisting of single crystal silicon semiconductors, Group IV semiconductors, Group II-VI compound semiconductors, Group III-V compound semiconductors, Group IV-IV compound semiconductors, mixed crystals thereof, and oxide semiconductors.

11. The semiconductor device according to claim 1, further comprising, in addition to the device part, a conductive layer and an electric element each formed on the substrate,
wherein the PMOS transistor is electrically connected to the electric element through the conductive layer.

12. The semiconductor device according to claim 1,
wherein the device part further includes an NMOS transistor,
the NMOS transistor includes a second electrical conduction path and a second gate electrode, and
the second electrical conduction path is provided inside the base layer on a side where the second gate electrode is disposed.

13. The semiconductor device according to claim 12,
wherein the second gate electrode contains N-type conductive polysilicon.

14. The semiconductor device according to claim 13,
wherein the second gate electrode contains an N-type impurity element.

15. The semiconductor device according to claim 14,
wherein the N-type impurity element comprises at least one of phosphorus and arsenic.

16. The semiconductor device according to claim 14,
wherein the concentration of the N-type impurity element is 1×10¹⁹ to 1×10²² cm⁻³.

17. The semiconductor device according to claim 12, further comprising, in addition to the device part, a conductive layer and an electric element each formed on the substrate,
wherein the PMOS transistor and the NMOS transistor are electrically connected to the electric element through the conductive layer.

18. A method of producing the semiconductor device according to claim 1,
the method comprising:
a separation layer-forming step that includes forming the PMOS transistor, and then forming a separation layer in part of the base layer, the separation layer containing a substance used for the separation;
a bonding step that includes bonding the substrate to the device part after the separation layer-forming step; and
a separation and removal step that includes separating and removing part of the base layer along the separation layer after the bonding step.

19. The method of producing the semiconductor device according to claim 18,
wherein the separation and removal step includes a heating treatment.

20. The method of producing the semiconductor device according to claim 18,
further comprising a step of further thinning the base layer after the separation and removal step.

21. A display device, comprising the semiconductor device according to claim 1.

22. A display device, comprising a semiconductor device produced by the production method according to claim 18.

23. A semiconductor device, comprising:
a substrate; and
a device part bonded to the substrate,
the device part including a base layer and a PMOS transistor,
the PMOS transistor being a surface channel MOS transistor.
